(19) United States
(12) Patent Application Publication
(10) Pub. No.: US 2012/0146074 A1
(43) Pub. Date: Jun. 14, 2012

(54) OPTICAL DEVICE

(75) Inventors: Yoshio Ariizumi, Fukuoka-ken (JP); Hatsuo Takezawa, Fukuoka-ken (JP)

(73) Assignee: KABUSHIKI KAISHA TOSHIBA, Tokyo (JP)

(21) Appl. No.: 13/117,434

(22) Filed: May 27, 2011

(30) Foreign Application Priority Data
Dec. 13, 2010 (JP) 2010-276840

(51) Int. Cl. H01L 33/50; H01L 31/0232

(52) U.S. Cl. 257/98; 257/432; 257/E31.129; 257/E33.061

(57) ABSTRACT

According to one embodiment, an optical device includes a lead, an optical element, and a sealing layer. The optical element is provided on the lead. The sealing layer is provided so as to cover the optical element. An upper surface of the sealing layer has a central portion including an optical axis of the optical element, a protrusion including an inner side surface surrounding the central portion and an outer side surface facing outward, and a connecting portion provided below the inner side surface and between the inner side surface and the central portion. The connecting portion includes a rounded portion on at least one of the inner side surface side and the central portion side. The outer side surface of the protrusion has average value of gradient angle larger than average value of gradient angle of a surface of the central portion.

### CROSS-REFERENCE TO RELATED APPLICATIONS

This application is based upon and claims the benefit of priority from the prior Japanese Patent Application No. 2010-276840, filed on Dec. 13, 2010; the entire contents of which are incorporated herein by reference.

### FIELD

Embodiments described herein relate generally to an optical device.

### BACKGROUND

An example of the optical device is a light emitting device used for illumination. Such a light emitting device requires that the light distribution angle of the emission light be controlled to within a prescribed range. For instance, a switch illumination requires that the light distribution angle be narrowed to increase the luminous intensity near the optical axis. Another example of the optical device is a light receiving device. The light receiving device, also requires that light received at a prescribed incident angle be efficiently guided to the light receiving region of the light receiving element.

The light emitting element and the light receiving element can be provided with a convex or concave lens. This facilitates controlling the light distribution angle of the light emitting device or the incident angle of the light receiving device. However, use of a hemispherical lens, for instance, makes it difficult to reduce the thickness of the light emitting device and the light receiving device, because the hemispherical lens has a large height. Furthermore, the step of externally attaching such a lens to the surface of the light emitting device or the light receiving device is difficult to incorporate into a continuous automatic assembly line.

### BRIEF DESCRIPTION OF THE DRAWINGS

FIG. 1A is a schematic plan view of a light emitting device according to a first embodiment, FIG. 1B is a schematic sectional view taken along line A-A, FIG. 1C is a schematic sectional view enlarging the light extraction surface;

FIG. 2A is a schematic sectional view illustrating the function of the light extraction surface of the embodiment, FIG. 2B is a schematic sectional view illustrating a method for approximating the spherical surface;

FIG. 3 is a graph of the directional characteristic of the light emitting device according to the first embodiment;

FIG. 4A is a schematic plan view of a light emitting device according to a variation of the first embodiment, FIG. 4B is a schematic sectional view taken along line A-A, FIG. 4C is a schematic sectional view enlarging the light extraction surface;

FIG. 5 is a schematic sectional view illustrating the function of the light extraction surface of the embodiment;

FIG. 6A is a schematic plan view of a light emitting device according to a second embodiment, FIG. 6B is its schematic sectional view;

FIG. 7A is a schematic plan view of a light emitting device according to a third embodiment, FIG. 7B is a schematic sectional view taken along line B-B;

FIG. 8A is a schematic sectional view illustrating the function of the third embodiment, FIG. 8B is a schematic sectional view illustrating the function of its variation;

FIG. 9 illustrates the function of a light emitting device according to a variation of the third embodiment;

FIG. 10A is a partial schematic sectional view of a light emitting device according to a fourth embodiment, FIG. 10B is a schematic sectional view of a concave lens, FIG. 10C is a graph of the directional characteristic;

FIG. 11A is a schematic sectional view of the lens of a light emitting device according to a fifth embodiment, FIG. 11B is a schematic sectional view of the combination lens before division, FIG. 11C is a graph of the directional characteristic;

FIG. 12A is a schematic sectional view of the lens of a light receiving device according to a sixth embodiment, FIG. 12B is a schematic sectional view of the light receiving device; and

FIG. 13A is a schematic plan view of a light emitting device according to a seventh embodiment, FIG. 13B is a schematic sectional view taken along line C-C.

### DETAILED DESCRIPTION

In general, according to one embodiment, an optical device includes a lead, an optical element, and a sealing layer.

The optical element is provided on the lead. The sealing layer is provided so as to cover the optical element. An upper surface of the sealing layer has a central portion including an optical axis of the optical element, a protrusion including an inner side surface surrounding the central portion and an outer side surface facing outward, and a connecting portion provided below the inner side surface and between the inner side surface and the central portion. The connecting portion includes a rounded portion on at least one of the inner side surface side and the central portion side. The outer side surface of the protrusion has average value of gradient angle larger than average value of gradient angle of a surface of the central portion.

Various embodiments will be described hereinafter with reference to the accompanying drawings.

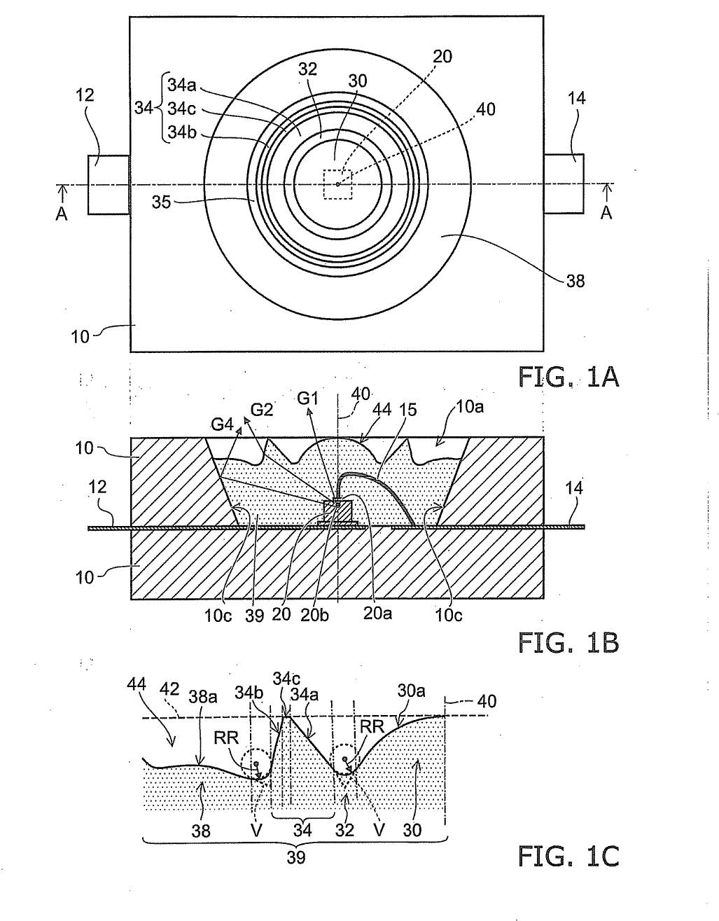

FIG. 1A is a schematic plan view of a light emitting device according to a first embodiment. FIG. 1B is a schematic sectional view taken along line A-A. FIG. 1C is a schematic sectional view enlarging the light extraction surface.

The light emitting device includes a molded body 10 made of an insulating material such as resin and ceramic, a first lead 12, a second lead 14, a light emitting element 20, a sealing layer 39, and a bonding wire 15. The light emitting element 20 is one of optical elements.

The molded body 10 includes a recess 10a. One end portion of the first lead 12 and one end portion of the second lead 14 are exposed at the bottom surface 10b of the recess 10a. The light emitting element 20 is bonded onto the first lead 12 with a conductive adhesive such as silver paste or with a metal solder, for instance. One electrode 20a provided on the upper surface of the light emitting element 20 is connected to the second lead 14 by the bonding wire 15. The sealing layer 39 made of e.g. silicone resin is provided in the recess 10a so as to cover the light emitting element 20. Here, if the molded body 10 is made of a thermoplastic resin containing a reflective filler, the sidewall 10c of the recess 10a can serve as a light reflecting surface.

Emission light from the light emitting element 20 can be extracted from an upper surface of the sealing layer 39, which acts as a light extraction surface. The light extraction surface 44 includes a central portion 30 including therein the optical axis 40 of the emission light, a first protrusion 34 surrounding the central portion 30, and a first connecting portion 32 provided between the central portion 30 and the first protrusion 34 and including a curved surface being concave upward. The first protrusion 34 includes an inner side surface 34a provided on the central portion 30 side, and an outer side surface 34b facing outside. In this figure, the connecting portion 32 is interposed between the central portion 30 and the first protrusion 34 and provided below the inner side surface 34a. The connecting portion 32 can connect between the gradient portion of the surface 30a of the central portion 30 and the gradient portion of the first protrusion 34, and includes a curved surface being concave upward. However, the curved surface of the connecting portion 32 is not limited thereto. For instance, the curved surface may include a plane, and a depression including a rounded portion provided on at least one of the inner side surface 34a side and the central portion 30 side. Here, the optical axis 40 of the light emitting element 20 is defines as an axis of an emission light.

The surface 30a of the central portion 30 can be formed as a planar or curved surface. In FIGS. 1A to 1C, the surface 30a of the central portion 30 includes a curved surface being convex upward. The upper end of the central portion 30 and the upper end of the first protrusion 34 may be included in the upper surface 42 of the cured sealing layer 39, or may be located below the upper surface 42.

The cross section of the first connecting portion 32 provided between the central portion 30 and the first protrusion 34 and including e.g. a curved surface being concave upward has a curvature radius RR of e.g. approximately 10-300 μm. A Fresnel lens or diffraction grating for converging coherent light such as laser light or increasing the light extraction efficiency often requires that the connecting portion between the protrusions include a sharp notch. However, in the embodiment, the refracting direction of incoherent emission light is changed to control the light distribution angle. Hence, the sharpness of the notch of the connecting portion can be relaxed.

The shape of the light extraction surface 44 including the protrusion and the connecting portion as described above can be formed by scanned laser light. For instance, by using carbon dioxide laser light having a wavelength near 10.6 μm, the depth of the connecting portion from the upper surface 42 of the sealing layer 39 can be set to e.g. approximately 300 μm. By irradiating the cured resin layer with the laser light, the resin layer can be formed into a desired shape of the connecting portion by sublimation, melting, or vaporization.

Experiments by the inventors have revealed that the curvature radius RR of the first connecting portion 32 between the central portion 30 and the first protrusion 34, and the width of the upper end tapered portion of the protrusion, are difficult to narrow to less than or equal to the wavelength of the processing laser light. Thus, in the case of using carbon dioxide laser light, for instance, the curvature radius RR of the rounded portion of the first connecting portion 32 is preferably larger than or equal to the wavelength of the carbon dioxide laser light, 10.6 μm. More preferably, the curvature radius RR is three times or more the wavelength of the laser light.

In the case of using laser light to remove the sealing layer 39 from the upper surface 42 to a prescribed depth, processing is facilitated by leaving a flat portion 34c at the upper end. In general, when the tip tapered portion of the protrusion is narrow, burrs are likely to occur. This makes it difficult to stabilize the shape and may change the light distribution angle. If rounded portions are provided on both sides of the flat portion 34c, the first protrusion 34 can be formed into a desired shape, and the light distribution characteristic can be controlled stably. That is, preferably, a rounded portion of 10.6 μm or more is provided at the upper end of the first protrusion 34. More preferably, the rounded portion is made larger than or equal to three times that size.

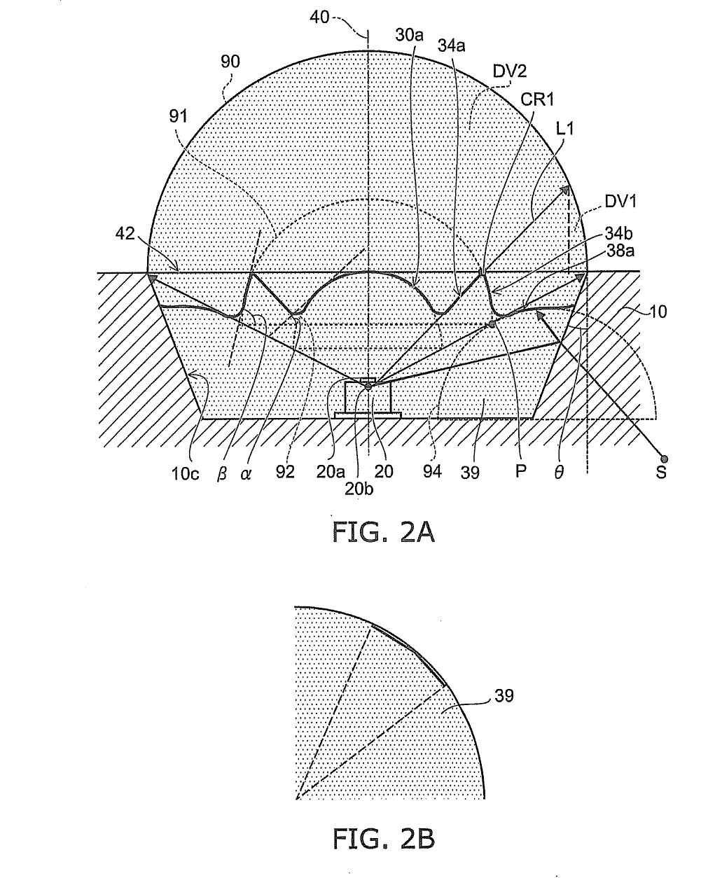

FIG. 2A is a schematic sectional view illustrating the function of the light extraction surface of the light emitting device of the embodiment. FIG. 2B is a schematic sectional view illustrating a method for approximating the spherical surface. It is assumed that a hemispherical lens 90 made of the same material as the sealing layer 39 is located on the sealing layer 39. Consider the situation in which one side of the hemispherical lens 90 is vertically bisected into DV1 and DV2, and the lens spherical surfaces are similarly moved toward the emission center 20b. That is, the curved surface is moved so that the direction of refraction by each spherical surface of the divided hemispherical lenses 90, 91 is parallel to that before the movement. Then, the average value 13 of the gradient angle of the spherical surface of the outer divided region DV1 is larger than the average value α of the gradient angle of the spherical surface of the divided region DV2 of the central portion 30. Here, the average value of the gradient angle is defined as the angle that the plane tangent to the curved surface including the spherical surface at the intermediate position between the upper end and the lower end of the curved surface makes with the upper surface 42.

The emission light from the light emitting element 20 is incoherent. Hence, there is no need to match the phase between the divided spherical regions. If the emission center 20b of the light emitting region is located at the center of similitude, hemispherical lenses similar to the hemispherical lens 90 can be successively arranged. The direction of refraction by the similarly reduced divided spherical surface can be made parallel to the direction of refraction by the spherical surface of the hemispherical lens 90. That is, if the emission center 20b is provided below the position of the center of the hemispherical lens, the emission light is emitted not radially from the emission center 20b, but the direction of refraction is made close to the optical axis 40. This further facilitates controlling the light distribution angle. Here, the center of a hemispherical lens is defined as the center of the circle that occurs when a spherical lens is bisected by a plane containing its center.

The divided reduced spherical surfaces can be arranged, for instance, with the upper ends of the respective spherical surfaces aligned. Alternatively, the spherical surfaces may be arranged with the lower surfaces aligned. Aligning the upper ends minimizes the region removed by laser processing from the upper surface 42 of the sealing layer 39 immediately after curing. This increases the productivity of forming the lens surface.

In the cross section shown in FIG. 2A, the similar hemispherical lenses 91, 92 can be moved along the straight line connecting the emission center (center of similitude) 20b to the upper bound of the sidewall (reflecting surface) 10c of the recess 10a of the molded body 10. In the first embodiment, a desired lens is formed by combining the reduced spherical surfaces of hemispherical lenses corresponding to vertically divided spherical surfaces. However, the angle of refraction by the spherical surface of the divided region DV2 near the optical axis 40 is small. In this figure, of the divided spherical lenses, the spherical surface of DV2 is reduced to obtain a hemispherical lens 92. Then, part of the hemispherical lens 92 is located so that its upper end is tangent to the upper surface 42 of the sealing layer 39 immediately after curing. The upper surface 30a of the central portion 30 is formed from this part of the hemispherical lens 92.

In the cross section, the outer side surface 34b is formed from the spherical surface of the hemispherical lens 91 obtained by reducing the spherical surface of the region DV1, the hemispherical lens 91 passing through the point CR1 at which the virtual ray L1 intersects the upper surface 42. The inner side surface 34a is formed from the transition portion from the hemispherical lens 92 to the hemispherical lens 91. As shown in this figure, if the transition portion (inner side surface) is matched with the trajectory of the virtual ray L1, the optical loss can be reduced.

As a result, as shown in FIG. 1B, in the emission light, the light G1 emitted from the surface 30a of the central portion 30 is refracted toward the optical axis 40 except the light on the optical axis 40. The light G2 emitted from the outer side surface 34b of the first protrusion 34 is refracted toward the optical axis 40. If the outer side surface is a curved surface, the gradient angle of the curved surface is defined by its average value. For instance, the average value 13 of the gradient angle of the outer side surface 34b of the first protrusion 34 is defined as the average value of the angle that the tangent to the spherical surface of the hemispherical lens 92 corresponding to the curved surface of the region DV1 makes with the plane parallel to the upper surface 42. The average value α of the gradient angle of the surface 30a of the central portion 30 is defined as the average value of the angle that the tangent to the surface 30a makes with the plane parallel to the upper surface 42. If the outer side surface 34b and the surface 30a are linear in cross section, the gradient angles are each constant. In FIG. 2A, the average value α of the gradient angle of the surface 30a of the central portion 30 is smaller than the average value ₁₃ of the gradient angle of the outer side surface 34b of the first protrusion 34b. The center of the hemispherical lens 90 is located above the emission center 20b. Hence, the incident angle to the outer side surface 34b does not vanish, and the light is refracted toward the optical axis 40. That is, as shown in FIG. 1B, the light G2 refracted by the outer side surface 34b is bent toward the optical axis 40 more greatly than the light G1 refracted by the curved surface 30a of the central portion 30. Thus, the sealing layer 39 acts as a converging lens.

In the case where the sidewall 10c of the recess 10a of the molded body 10 serves as a reflecting surface, a peripheral portion 38 further provided outside the first protrusion 34 makes it easier to control the light distribution angle. The light emitted toward the side surface of the light emitting element 20 is reflected by the sidewall 10c having a gradient angle θ, and changes its traveling direction. It can be supposed that the reflected light is virtually emitted from the point S symmetric to the emission center 20b with respect to the reflecting surface (sidewall 10c).

The intersection point of the straight line connecting the upper end of the sidewall 10c and the emission center 20b and the spherical surface of the hemispherical lens 91 is denoted as point P. Here, a peripheral portion 38a is provided so that the spherical surface of the hemispherical lens 94 obtained by similarly reducing the hemispherical lens 90 with the center of similitude placed at the symmetric point S passes through the point P in cross section. The light G4 reflected by the sidewall 10c and emitted from the curved surface 38a of the peripheral portion 38 can be refracted toward the optical axis 40. This further facilitates controlling the light distribution angle. In this case, the first connecting portion 32 provided between the central portion 30 and the first protrusion 34 also constitutes the light extraction surface 44. In the embodiment, the direction of refraction by the similarly reduced spherical surface 38a is parallel to the direction of refraction by the spherical surface of the hemispherical lens 90. This facilitates controlling the light distribution angle. Furthermore, it is easy to reduce the thickness of the light emitting device. In the case where highly strict converging is not required, a certain effect can be expected also by using a surface whose cross section is a straight line having an angle nearly corresponding to the spherical surface, or by using a combination of a plurality of such surfaces (FIG. 2B). Here, the curved surface of the central portion 30 and the outer side surface of the first protrude 34 may not be similar. That is, the central portion 30 may include part of a spherical surface being convex upward, and the outer side surface 34b of the first protrude 34 may include a surface obtained by rotating a curve being convex upward about the optical axis 40.

In existing optical devices, a hemispherical lens formed in a separate step is provided above the sealing layer. However, the manufacturing process is complicated, and not easy to automate. More specifically, after the light emitting element is bonded and subjected to wire bonding, a liquid sealing resin is filled and subjected to primary curing by e.g. heating.

Subsequently, the workpiece is turned upside down and fixed into a casting type case mold filled with a liquid resin, which is cured by e.g. heating. After extraction (releasing) from the case mold, secondary curing is performed. Thus, a lens type SMD (surface mounted device) light emitting device is completed. As described above, the steps such as positioning, attaching/detaching from the heating apparatus, and releasing are not suitable for a continuous automation line.

In contrast, the light emitting device of the embodiment does not need such steps as positioning, attaching/detaching from the heating apparatus, and releasing. By an automated laser processing apparatus, the surface of a flat sealing layer is irradiated with scanned laser light. The laser light irradiation time is easily set to e.g. one second or less, and is suitable for a continuous automation line. This increases volume productivity and facilitates cost reduction.

Here, as the curvature radius RR of the first connecting portion 32 becomes smaller, the optical loss can be reduced more significantly. However, as shown in FIG. 1C, even in the connecting portion having a rounded cross section, most of the light emitted from the connecting portion can be extracted if the curvature radius RR of the rounded portion is in the range of 10-300 μm. Furthermore, experiments by the inventors have revealed that the lens effect is weakened if the curvature radius RR is larger than 300 μm. That is, the curvature radius RR is preferably set to 300 μm or less.

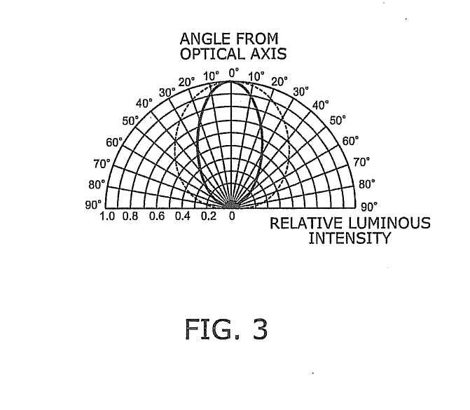

FIG. 3 is a graph of the directional characteristic of the light emitting device according to the first embodiment.

The radial direction represents the relative luminous intensity, and the circumferential direction represents the angle from the optical axis 40. In the first embodiment shown by the solid line, the full width at half maximum can be narrowed to 60 degrees. Thus, the light distribution angle is reduced. In contrast, in the sealing layer having a flat surface (dashed line), the full width at half maximum is doubled to 120 degrees. Consequently, the luminous intensity on the optical axis 40 of the light emitting device can be increased to generally 3.5 times that of the light emitting device having a flat surface.

In laser processing, it is difficult to form a sharp connecting portion, and a rounded cross section is formed. FIGS. 1A to 1C show a light emitting device with the curvature radius RR of the rounded portion set to 50 μm. In this light emitting device, as shown in FIG. 3, it is sufficiently possible to control the light distribution angle. Furthermore, excimer laser light, for instance, has a wavelength as short as 248 nm. Hence, use of excimer laser light facilitates further reducing the curvature radius of the rounded portion formed by laser processing.

In the light emitting device of the embodiment, the emission light is not radially spread. Thus, the light emitting device of the embodiment is suitable for applications to increase the luminous intensity near the optical axis 40, such as switch illumination and spot illumination. In the case where the light emitting element 20 includes In.(Al_{y}Ga_{1-y})₁₋ₓP (0≦x≦1, 0≦y≦1), light in the wavelength range from green to red can be emitted. In the case where the light emitting element 20 includes InₓAl_{y}Ga_{1-x-y}N (0≦x≦1, 0≦y≦1, x+y≦1), light in the range from ultraviolet to blue can be emitted. In this case, if phosphor particles are mixed in the sealing layer 39, the light distribution angle of mixed light such as white light can be easily controlled.

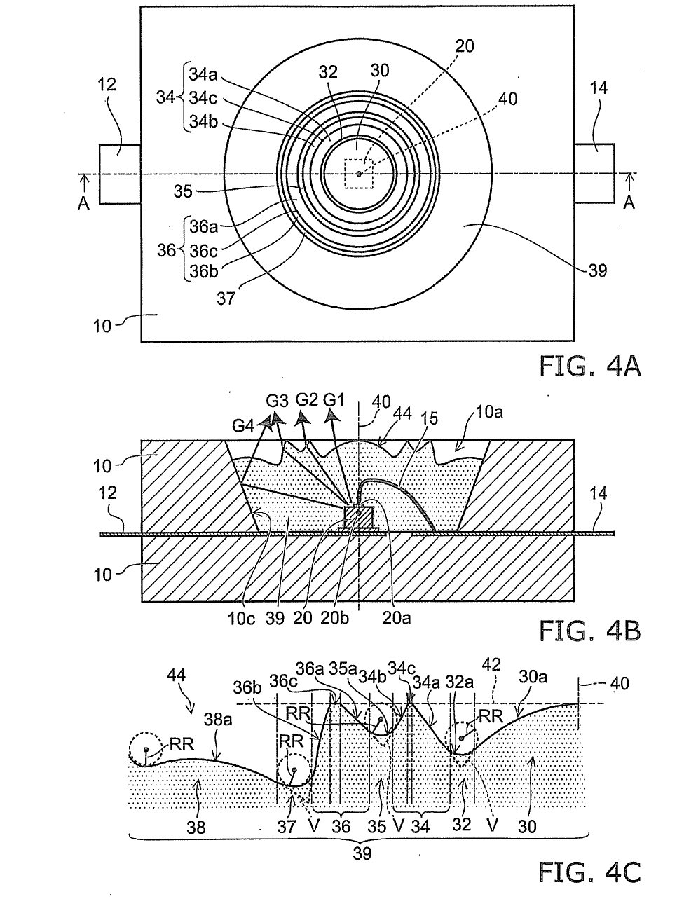

FIG. 4A is a schematic plan view of a light emitting device according to a variation of the first embodiment. FIG. 4B is a schematic sectional view taken along line A-A. FIG. 4C is a schematic sectional view enlarging the light extraction surface.

The light emitting device includes a molded body 10, a first lead 12, a second lead 14, a light emitting element 20, a sealing layer 39, and a bonding wire 15.

The light extraction surface 44 includes a central portion 30 including therein the optical axis 40, a first protrusion 34 surrounding the central portion 30, a second protrusion 36 surrounding the first protrusion 34, a first connecting portion 32 provided between the central portion 30 and the first protrusion 34, and a second connecting portion 35 provided between the first protrusion 34 and the second protrusion 36. The first protrusion 34 includes an inner side surface 34a provided on the central portion 30 side, and an outer side surface 34b provided on the second protrusion 36 side. The second protrusion 36 includes an inner side surface 36a surrounding the first protrusion 34 and provided on the first protrusion 34 side, and an outer side surface 36b facing outside. The second connecting portion 35 provided between the outer side surface 34b of the first protrusion 34 and the inner side surface 36a of the second protrusion 36 includes e.g. a curved surface being concave upward. The second connecting portion 35 may include a flat surface, and a rounded portion provided on at least one of the first protrusion 34 side and the second protrusion 36 side.

Laser processing is facilitated by leaving a flat portion 36c at the upper end of the second protrusion 36. If rounded portions are provided on both sides of the flat portion 36c, the second protrusion 36 can be formed into a desired shape, and the light distribution characteristic can be controlled stably.

That is, preferably, a rounded portion of 10.6 μm or more is provided at the upper end of the second protrusion 36. More preferably, the rounded portion is made larger than or equal to three times that size.

The surface 30a of the central portion 30 is formed as a planar or curved surface. In FIGS. 4A to 4C, the surface 30a of the central portion 30 includes a curved surface being convex upward. The upper ends of the central portion 30, the first protrusion 34, and the second protrusion 36 may be located in the upper surface 42 of the cured sealing layer 39, or may be located below the upper surface 42.

The cross section of the rounded portion of the second connecting portion 35 provided between the first protrusion 34 and the second protrusion 36 has a curvature radius RR of e.g. approximately 10-300 μm.

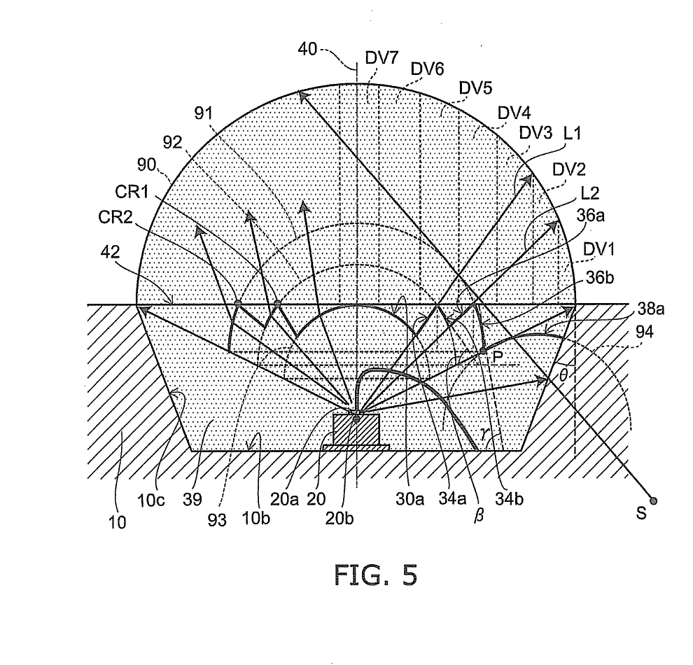

FIG. 5 is a schematic sectional view illustrating the function of the light extraction surface of the light emitting device of the embodiment.

It is assumed that a hemispherical lens 90 made of the same material as the sealing layer 39 is located on the sealing layer 39. Consider the situation in which one side of the hemispherical lens 90 is concentrically and vertically divided into seven parts, and the lens spherical surfaces are similarly moved toward the emission center 20b. That is, the curved surface is moved so that the direction of refraction by each spherical surface of the divided hemispherical lenses (DV1-DV7) is parallel to that before the movement. Here, the gradient angle of the spherical surface of the outer divided region is large. This increases the height of the corresponding protrusion. Thus, in the variation, the division spacing of DV1 and DV2 is set to half that of the other regions to reduce the corresponding height.

In the cross section shown in FIG. 5, the similar hemispherical lenses 91, 92, 93 can be moved along the straight line connecting the emission center (center of similitude) 20b to the upper end of the sidewall (reflecting surface) 10c of the recess 10a of the molded body 10. In the variation, a desired lens is formed by combining the reduced spherical surfaces of hemispherical lenses corresponding to vertically divided spherical surfaces. However, the angle of refraction by the spherical surface of the divided region DV7 near the optical axis 40 is small. Thus, in this figure, of the divided spherical lenses, DV3-DV7 are integrated into one spherical surface and reduced to obtain a hemispherical lens 93. Then, part of the hemispherical lens 93 is located so that its upper end is tangent to the upper surface 42 of the sealing layer 39 immediately after curing. The upper surface 30a of the central portion 30 is formed from this part of the hemispherical lens 93.

In the cross section, the surface 34b is formed from the spherical surface of the hemispherical lens 92 obtained by reducing the spherical surface of the region DV2, the hemispherical lens 92 passing through the point CR1 at which the virtual ray L1 intersects the upper surface 42. The inner side surface 34a is formed from the transition portion from the hemispherical lens 93 to the hemispherical lens 92.

Furthermore, the surface 36b is formed from the spherical surface of the hemispherical lens 91 obtained by reducing the spherical surface of the region DV1, the hemispherical lens 91 passing through the point CR2 at which the virtual ray L2 intersects the upper surface 42. The inner side surface 36a is formed from the transition portion from the hemispherical lens 92 to the hemispherical lens 91. If this transition portion is matched with the trajectory of the virtual ray L2, the optical loss can be reduced. The number of divisions and the division spacing of the hemispherical lens are not limited to FIGS. 4A to 4C.

As a result, as shown in FIG. 4B, in the emission light, the light G1 emitted from the surface 30a of the central portion 30 is refracted toward the optical axis 40. The light G2 emitted from the outer side surface 34b of the first protrusion 34 is refracted toward the optical axis 40. The light G3 emitted from the outer side surface 36b of the second protrusion 36 is refracted toward the optical axis 40. The average value β of the gradient angle of the outer side surface 34b of the first protrusion 34 is defined as the average value of the angle that the tangent to the spherical surface of the hemispherical lens 92 corresponding to the curved surface of the region DV2 makes with the plane parallel to the upper surface 42. The average value γ of the gradient angle of the outer side surface 36b of the second protrusion 36 is defined as the average value of the angle that the tangent to the spherical surface of the hemispherical lens 91 corresponding to the curved surface of the region DV1 makes with the plane parallel to the upper surface 42.

The average value β of the gradient angle of the outer side surface 34b of the first protrusion 34 is smaller than the average value γ of the gradient angle of the outer side surface 36b of the second protrusion 36. Hence, as shown in FIG. 4B, the light G3 refracted by the outer side surface 36b of the second protrusion 36 is bent toward the optical axis 40 more greatly than the light G2 refracted by the outer side surface 34b of the first protrusion 34. Thus, the sealing layer 39 acts as a converging lens.

In the case where the sidewall 10c of the recess 10a of the molded body 10 serves as a reflecting surface, a peripheral portion 38 further provided outside the second protrusion 36 makes it easier to control the light distribution angle. The light emitted toward the side surface of the light emitting element 20 is reflected by the sidewall 10c having a gradient angle θ, and changes its traveling direction. It can be supposed that the reflected light is virtually emitted from the point S symmetric to the emission center 20b with respect to the reflecting surface (sidewall 10c).

The intersection point of the straight line connecting the upper end of the sidewall 10c and the emission center 20b and the spherical surface of the hemispherical lens 91 is denoted as point P. Here, a peripheral portion 38 is located so that the spherical surface of the hemispherical lens 94 obtained by similarly reducing the hemispherical lens 90 with the center of similitude placed at the symmetric point S passes through the point P in cross section. The light G4 reflected by the sidewall 10c and emitted from the curved surface 38a of the peripheral portion 38 can be refracted toward the optical axis 40. This further facilitates controlling the light distribution angle. In this case, a third connecting portion 37 provided between the second protrusion 36 and the peripheral portion 38 also constitutes the light extraction surface 44.

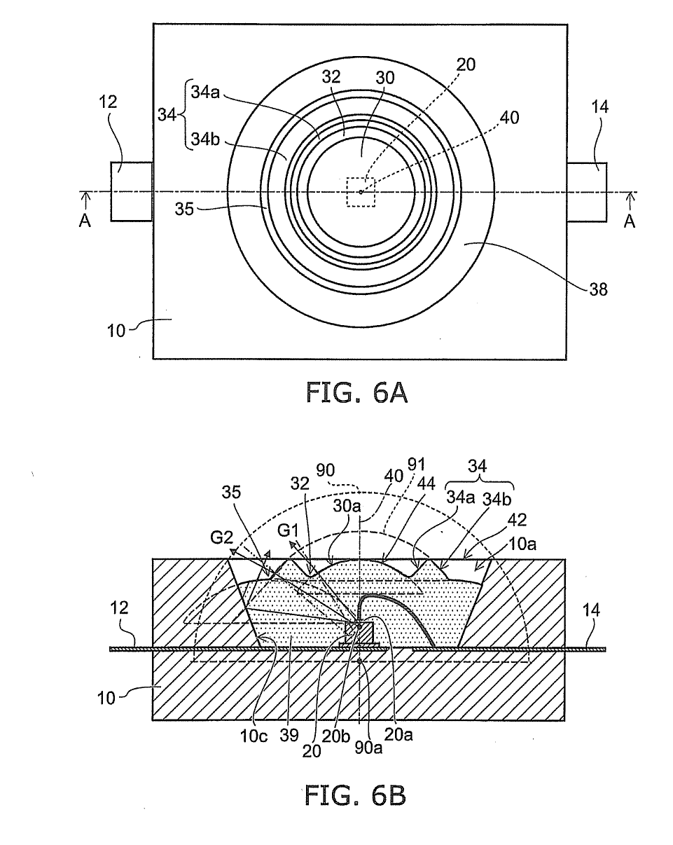

Here, as the curvature radius RR of the first connecting portion 32, the second connecting portion 35, and the third connecting portion 37 becomes smaller, the optical loss can be reduced more significantly. FIG. 6A is a schematic plan view of a light emitting device according to a second embodiment. FIG. 6B is a schematic sectional view taken along line A-A.

In the second embodiment, the emission center 20b is located above the center 90a of the hemispherical lens 90. Hence, the incident angle to the outer side surface 34b of the first protrusion 34 does not vanish, and the light G2 is refracted away from the optical axis 40. The light G1 refracted by the surface 30a of the central portion 30 travels away from the optical axis 40. Furthermore, the light G2 refracted by the outer side surface 34b of the first protrusion 34 is bent outward more greatly than the light G1 refracted by the surface 30a of the central portion 30. However, the spread of light can be reduced as compared with the case where the upper surface 42 of the sealing layer 39 is flat.

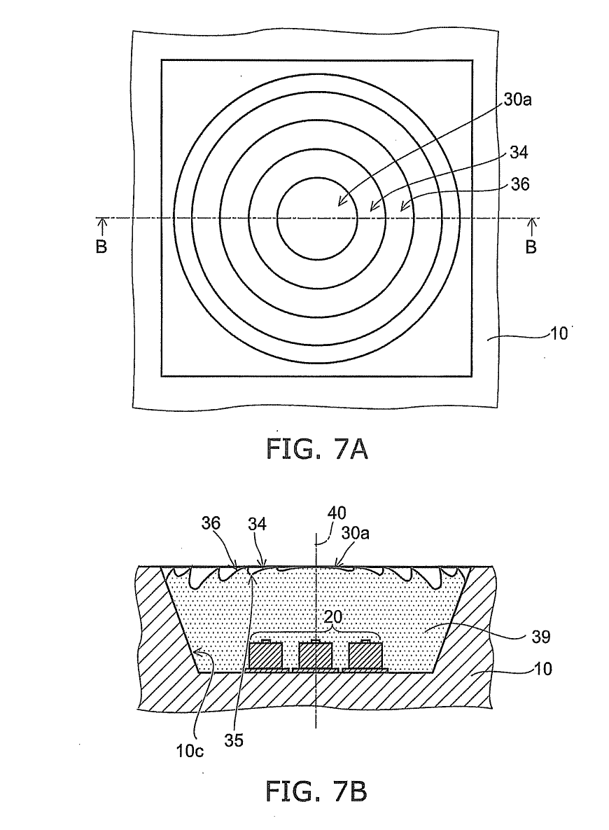

FIG. 7A is a schematic plan view of a light emitting device according to a third embodiment. FIG. 7B is a schematic sectional view taken along line B-B.

The third embodiment is suitable for an optical device in which a plurality of light emitting elements are built into one package, or the light emitting element has a large light emission area. In the structure shown in FIGS. 7A and 7B, the inner side surface constituting the transition portion is parallel to the optical axis 40, and the outer side surface serves as a refracting surface. In this structure, the size of each lens region can be arbitrarily selected. That is, the effective light source size can be easily enlarged in the case of using a large-area light emitting element or a plurality of light emitting elements arranged next to each other.

In this case, the second connecting portion 35 between the spherical surfaces 34b and the inner side surface 36a has a curved surface being concave upward, for instance. The curvature radius RR of the connecting portion 35 in cross section can be set to e.g. 10-300 μm. In the third embodiment, the light extraction efficiency can be made higher than in the light emitting device including a sealing layer 39 with a flat upper surface. Furthermore, the light distribution angle can be controlled by changing the shape of the light extraction surface 44.

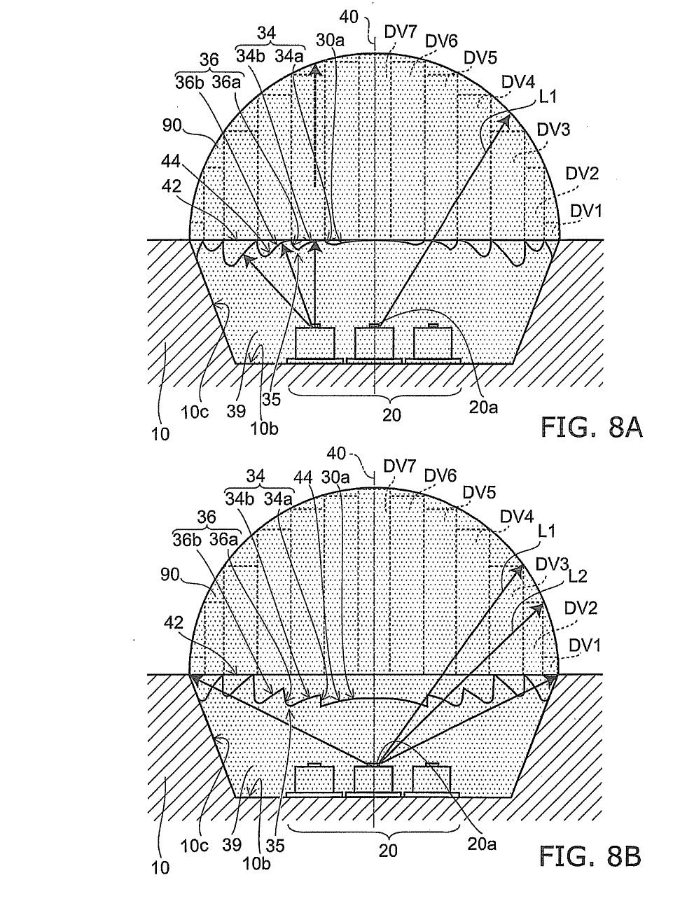

FIG. 8A is a schematic sectional view illustrating the function of the third embodiment. FIG. 8B is a schematic sectional view illustrating the function of its variation.

The spherical surfaces of the hemispherical lens divided into DV2-DV7 are located below the upper surface 42 of the sealing layer 39 immediately after curing. In FIG. 8A, the upper ends of the respective divided spherical surfaces are located flush with each other. In FIG. 8B, the spherical surfaces corresponding to the divided regions DV4-7 are located below the upper surface 42 of the sealing layer 39 immediately after curing. Thus, by changing the vertical position of the divided spherical surfaces in the sealing layer 39, the controllable range of the light distribution angle can be made wider. On the contrary, as an alternative structure, the positions of the protrusions can be lowered toward the outside so that the light emitted from an inner protrusion is less likely to be incident on the outer protrusion and refracted thereby.

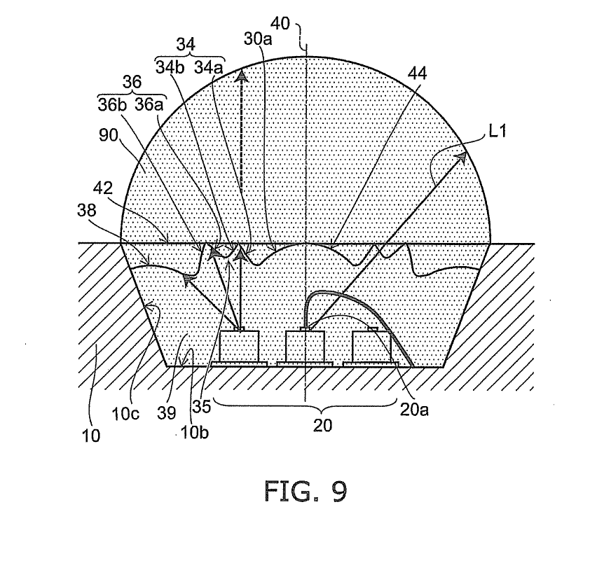

FIG. 9 illustrates the function of a light emitting device according to a variation of the third embodiment.

In this figure, the light extraction surface 44 used in the first embodiment is provided above three light emitting elements 20. The light beam emitted from the central light emitting element 20 is in good agreement with the light beam position of the original hemispherical lens. However, the upward light emitted most from the light emitting elements 20 on both sides impinges on the inner side surface 34a constituting the transition portion. In this case, the incident angle is different from that on the spherical surface of the original hemispherical lens shown by the dashed line. Thus, in the case where the light source has a large area, it is more preferable that the inner side surface constituting the transition portion be parallel to the optical axis direction as shown in FIGS. 7A to 8B in order to realize a light distribution characteristic close to that of the original hemispherical lens.

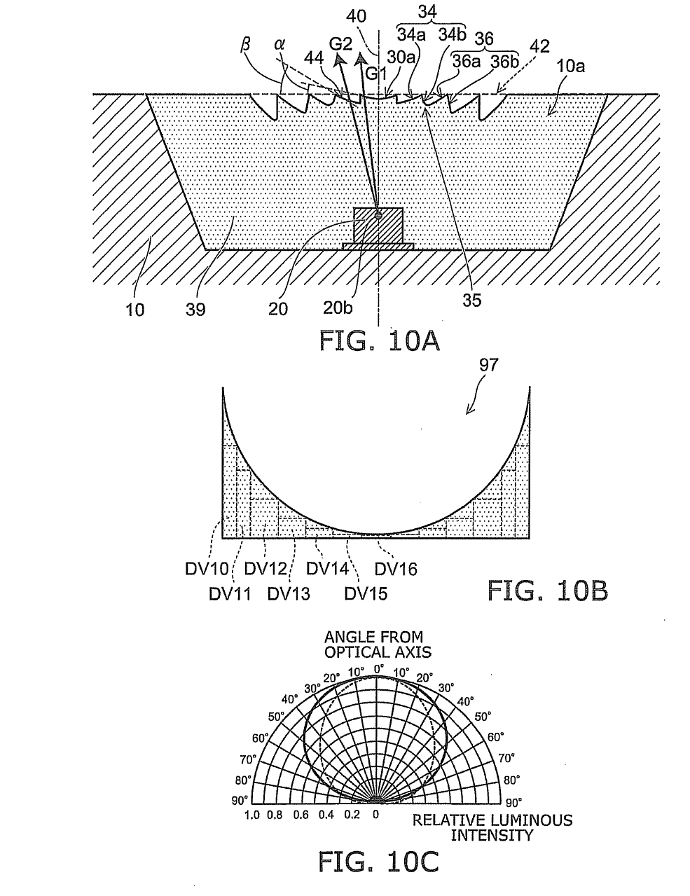

FIG. 10A is a partial schematic sectional view of a light emitting device according to a fourth embodiment. FIG. 10B is a schematic sectional view of a concave lens. FIG. 10C is a graph of the directional characteristic.

In FIG. 10A, a concave lens is provided at the surface of the sealing layer 39. As shown in FIG. 10B, the concave lens 97 is divided into DV10-DV16. The curved surfaces thereof are moved to below the upper surface 42 of the sealing layer 39 immediately after curing.

If the inner side surface is a curved surface, the gradient angle of the curved surface is defined by its average value. For instance, the average value β of the gradient angle of the inner side surface 34a of the first protrusion 34 is defined as the average value of the angle that the tangent to the inner side surface 34a makes with the upper surface 42. The average value α of the gradient angle of the surface 30a of the central portion 30 is defined as the average value of the angle that the tangent makes with the upper surface 42. The average value of the gradient angle of the inner side surface 34a of the first protrusion 34 is larger than the average value α of the gradient angle of the surface 30a of the central portion 30. Hence, the light G2 refracted by the inner side surface 34a of the first protrusion 34 is bent away from the optical axis 40 more greatly than the light G1 refracted by the surface 30a of the central portion 30. Thus, the sealing layer 39 acts as a diverging lens. Here, the curved surface can be obtained by similarly reducing the divided region of the concave lens. This further facilitates controlling the light distribution angle.

As shown in FIG. 10C, in the light emitting device including a sealing layer with a flat upper surface, the full width at half maximum (dashed line) is 120 degrees. On the other hand, in the fourth embodiment shown by the solid line, the full width at half maximum is 135 degrees. Thus, the light distribution angle is widened, and light can be emitted in a wide range.

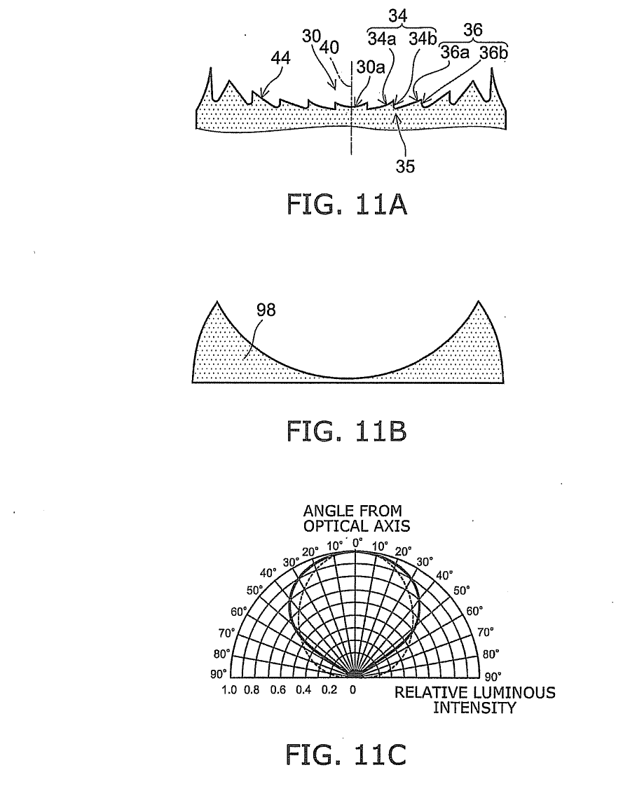

FIG. 11A is a schematic sectional view of the lens of a light emitting device according to a fifth embodiment. FIG. 11B is a schematic sectional view of the combination lens before division. FIG. 11C is a graph of the directional characteristic.

As shown in FIG. 11B, the lens before division used in the fifth embodiment is a combination lens 98 capable of acting as a concave lens in the central portion 30 and as a convex lens in the peripheral portion. For instance, the light emitted from the recess 30a of the central portion 30, the light emitted from the inner side surface 34a of the first protrusion 34, and the light emitted from the inner side surface 36a of the second protrusion 36 are each refracted outward away from the optical axis 40. When such a combination lens is used, the light is diverged in the region near the optical axis 40, and relatively converged in the region distant from the optical axis 40. As a result, for instance, the luminous intensity in the angular range of 30 degrees or less from the optical axis 40 can keep 90% or more of the luminous intensity on the optical axis 40. Furthermore, in the case where the light extraction surface 44 is rectangular or elliptical, preferably, the curved surface of an elliptical lens is divided and combined into a curved surface.

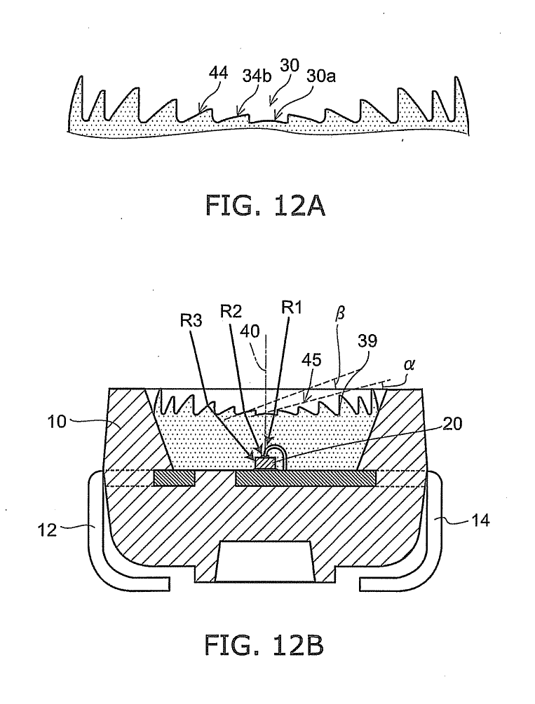

FIG. 12A is a schematic sectional view of the lens of a light receiving device according to a sixth embodiment. FIG. 12B is a schematic sectional view of the light receiving device.

The light receiving device includes a molded body 10, a first lead 12, a second lead 14, a light receiving element 20, and a sealing layer 39. The light receiving element 20 is one of optical elements.

The molded body 10 includes a recess 10a. One end portion of the first lead 12 and one end portion of the second lead 14 are exposed at the bottom surface 10b of the recess 10a. The light receiving element 20 such as a photodiode, phototransistor, and light receiving IC is bonded onto the first lead 12 with a conductive adhesive or metal solder, for instance. The sealing layer 39 made of e.g. silicone resin is provided in the recess 10a so as to cover the light receiving element 20.

An incident surface 45 having a cross section shown in FIG. 12B is formed at the upper surface of the sealing layer 39 by laser processing. In this case, the average value β of the gradient angle of the outer side surface 34b of the first protrusion 34 is larger than the average value α of the gradient angle of the surface 30a of the central portion 30. Thus, the incident light R2 injected into the outer side surface 34b is bent toward the optical axis 40 more greatly than the incident light R1 injected into the surface 30a of the central portion 30. An optical axis 40 of the light receiving element 20 is defined as a central axis of a light receiving layer, as shown in FIG. 12B. This facilitates increasing the light receiving sensitivity of the light receiving element 20.

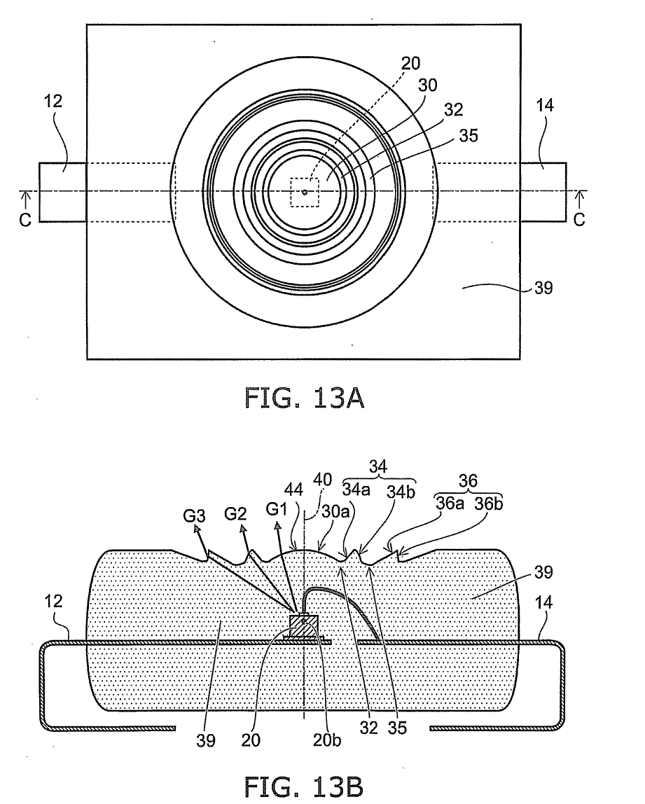

FIG. 13A is a schematic plan view of a light emitting device according to a seventh embodiment. FIG. 13B is a schematic sectional view taken along line C-C.

The light emitting device includes a first lead 12, a second lead 14, a light emitting element 20, and a sealing layer 39 made of a molded resin. The light emitting element 20 is bonded onto the first lead 12 with a conductive adhesive or metal solder, for instance. The sealing layer 39 can be formed from e.g. silicone resin by e.g. transfer molding. The light G1 refracted by the central portion 30, the light G2 refracted by the first protrusion 34, and the light G3 refracted by the second protrusion 36 are refracted toward the optical axis 40. Thus, the light distribution angle can be controlled. A light extraction surface 44 is provided at the surface of the sealing layer 39. This facilitates controlling the light distribution angle.

As a method for specifically realizing the curved surface described herein, it is contemplated to use a spherical surface having a certain curvature radius, a combination of spherical surfaces having a plurality of different curvature radii, and an aspherical curved surface. Furthermore, as shown in FIG. 12B, a combination of planes can also achieve an effectively equivalent effect.

In the optical devices according to the above first to seventh embodiment and the variations associated therewith, it is easy to control the light distribution angle of emission light from a light emitting element, or the incident angle of incident light to a light receiving element. The thickness of these optical devices can be easily reduced. Furthermore, a continuous automatic assembly line can be used. This enables cost reduction of the light emitting device and the light receiving device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An optical device comprising:
a lead;
an optical element provided on the lead ; and
a sealing layer provided so as to cover the optical element, an upper surface of the sealing layer having a central portion including an optical axis of the optical element, a protrusion including an inner side surface surrounding the central portion and an outer side surface facing outward, and a connecting portion provided below the inner side surface and between the inner side surface and the central portion,
the connecting portion including a rounded portion on at least one of the inner side surface side and the central portion side, and
the outer side surface of the protrusion having average value of gradient angle larger than average value of gradient angle of a surface of the central portion.

2. The device according to claim 1, wherein
the optical element is a light emitting element being capable of emitting emission light through the upper surface of the sealing layer.

3. The device according to claim 2, wherein
the central portion includes part of a first curved surface being convex upward, and
the outer side surface of the protrusion includes part of a second curved surface obtained by similarly enlarging the first curved surface with center of similitude placed at emission center of the light emitting element.

4. The device according to claim 3, wherein the first curved surface and the second curved surface are each a hemisphere and position of center of the hemisphere of the first curved surface is closer to the emission center than position of center of the hemisphere of the second curved surface.

5. The device according to claim 3, wherein the first curved surface and the second curved surface are each a hemisphere and position of center of the hemisphere of the first curved surface is farther from the emission center than position of center of the hemisphere of the second curved surface.

6. The device according to claim 2, wherein the central portion includes part of a first curved surface being convex upward and the outer side surface of the protrusion includes a second curved surface obtained by rotating part of a curve being convex upward about the optical axis.

7. The device according to claim 2, wherein the outer side surface of the protrusion includes a curved surface being convex upward and refracts the emission light toward the optical axis.

8. The device according to claim 2, wherein the sealing layer includes a phosphor particle.

9. The device according to claim 1, wherein the rounded portion of the connecting portion has a curvature radius of 10 μm or more and 300 μm or less.

10. The device according to claim 1, further comprising:
a molded body including a recess having a bottom surface and a sidewall, the optical element being exposed at the bottom surface.

11. The device according to claim 1, wherein
the optical element is a light receiving element being capable of receiving an incident light through an upper surface of the sealing layer.

12. The device according to claim 1, wherein the protrusion includes an effectively flat upper surface.

13. The device according to claim 1, wherein the central portion includes an effectively flat upper surface.

14. An optical device comprising:
a lead;
an optical element provided on the lead; and
a sealing layer provided so as to cover the optical element, an upper surface of the sealing layer having a central portion including an optical axis of the optical element, a protrusion including an inner side surface surrounding the central portion and an outer side surface facing outward, and a connecting portion provided below the inner side surface and between the inner side surface and the central portion,
the connecting portion including a rounded portion on at least one of the inner side surface side and the central portion side, and
the inner side surface of the protrusion having average value of gradient angle larger than the average value of the gradient angle of the surface of the central portion.

15. The device according to claim 14, wherein
the optical element is a light emitting element being capable of emitting emission light through the upper surface of the sealing layer.

16. The device according to claim 15, wherein the inner side surface of the protrusion includes a curved surface being concave upward and refracts the emission light away from the optical axis.

17. The device according to claim 15, wherein the sealing layer includes a phosphor particle.

18. The device according to claim 14, wherein the rounded portion of the connecting portion has a curvature radius of 10 μm or more and 300 μm or less.

19. The device according to claim 14, wherein the protrusion includes an effectively flat upper surface.

20. The device according to claim 14, wherein the central portion includes an effectively flat upper surface.
